(19) United States
(12) Patent Application Publication
(10) Pub. No.: US 2011/0147923 A1
(43) Pub. Date: Jun. 23, 2011

(54) Surface Mounting Integrated Circuit Components

(76) Inventor: Jiun Hann Sir, Bayan Lepas (MY)

(21) Appl. No.: 12/643,074

(22) Filed: Dec. 21, 2009

(51) Int. Cl. H01L 23/488; H01L 21/60

(52) U.S. Cl. 257/737; 438/615; 257/E21.508; 257/E23.023

(57) ABSTRACT

An electronic apparatus may include a first component solder bonded to a second component. The first component may be, for example, an integrated circuit. The first component may have an array of metallic protrusions. Those protrusions may be coupled to circuit elements within said first component. The second component may include a plurality of solder portions coupled to the second component and engaged by the protrusions on the first component in a soldered connection.

### BACKGROUND

This relates generally to surface mounting and, particularly, to surface mounting one electronic component to another.

Surface mounting generally involves soldering one component to another upon the application of heat. Typically, solder balls and solder paste are positioned between the components and printed circuit boards to be connected and heat is applied in a process called reflow. As a result, the two components are secured together.

These solder balls have resulted in finer interconnection pitches, meaning that more connections can be made per unit of surface area between integrated circuit components. At the same time, solder ball joints are prone to failure between the solder ball and the connected components. The failure mechanisms may be various, but include fatigue failure and shock failure.

### BRIEF DESCRIPTION OF THE DRAWINGS

FIG. 1 is an enlarged, cross-sectional view of one embodiment of the present invention;

FIG. 2 is an enlarged, cross-sectional view at an early stage in accordance with one embodiment;

FIG. 3 is an enlarged, cross-sectional view at a subsequent stage in accordance with one embodiment;

FIG. 4 is an enlarged, cross-sectional view at a subsequent stage showing the creation of routing in accordance with one embodiment;

FIG. 5 is an enlarged, cross-sectional view according to one embodiment using dry film development to reveal the routing in accordance with one embodiment;

FIG. 6 is an enlarged, cross-sectional view showing copper plating to form via studs in accordance with one embodiment;

FIG. 7 is an enlarged, cross-sectional view showing electro-less copper plating in accordance with one embodiment;

FIG. 8 is an enlarged, cross-sectional view showing dry film patterning in accordance with one embodiment;

FIG. 9 is an enlarged, cross-sectional view showing the formation of a build up layer in accordance with one embodiment;

FIG. 10 is an enlarged, cross-sectional view showing metal plating in accordance with one embodiment;

FIG. 11 is an enlarged, cross-sectional view showing the separation of panels in the removal of a core in accordance with one embodiment;

FIG. 12 is an enlarged, cross-sectional view of a film removal to reveal a via stud in accordance with one embodiment; and

FIG. 13 is an enlarged, cross-sectional view showing attachment of a substrate bump according to one embodiment.

### DETAILED DESCRIPTION

In accordance with some embodiments, a surface mounting arrangement may use protruding studs that engage solder paste and produce a more secure connection. When one component, having protruding studs, is pressed against another component having solder paste in the same arrangement as the studs, the studs penetrate into and engage the solder paste, creating a more secure surface mount connection. In some embodiments, the more secure connection is due to (1) the greater surface area of contact between the stud and the solder paste compared to conventional connections between relatively flat, planar lands and solder balls and (2) the greater strength of the stud in lateral loading.

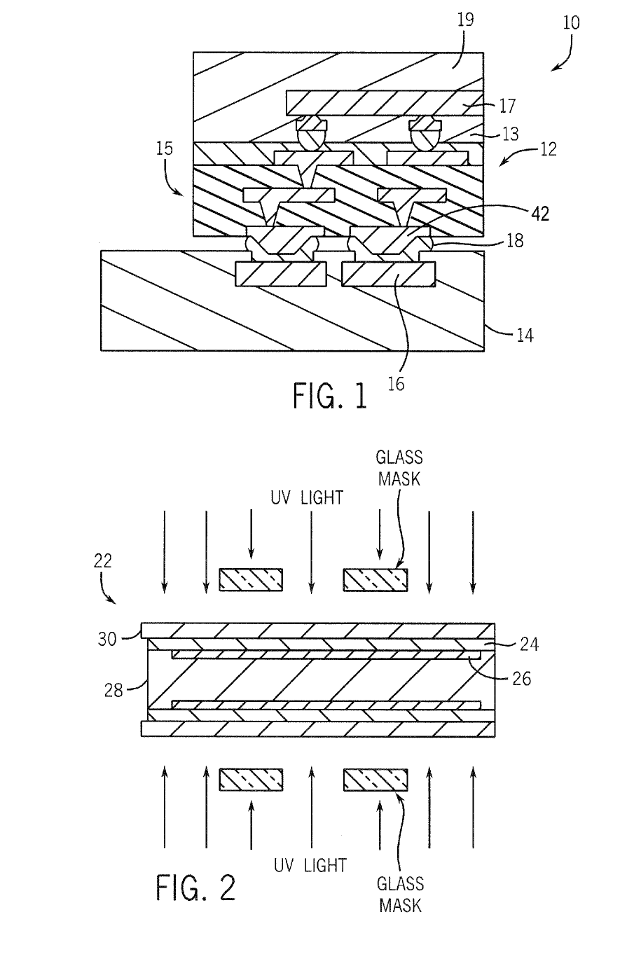

Referring to FIG. 1, in accordance with one embodiment, a surface mounted apparatus 10 may include an integrated circuit component 12 surface mounted on a printed circuit board 14, such as a motherboard. The component 12 may be a packaged or unpackaged integrated circuit board, substrate, or combination of integrated circuits, to mention a few examples. The printed circuit board 14 may include internal routing 16 coupled to solder 18. The solder may be a paste deposited on the board 14, for example. The paste may be comprised of micro-balls in a flux matrix in one embodiment. The solder has flowed during a reflow process to assume a U-shape while in contact with engaging protrusions or via studs 42 on the component 12. The U-shape is due to placement pressure that may cause the studs to sink into and penetrate the paste during reflow. The melted paste may wick up the studs in some cases. After the stud is wetted by solder, the solder may collapse, causing further stud penetration of solder.

In one embodiment, the studs may be conical and, particularly, frustoconical. The studs protrude outwardly of the lower surface of the component 12, in one embodiment. The component 12 includes an array or matrix of studs and the board 14 may have a matching array or matrix of solder.

The component 12 may include a Direct Laser and Lamination (DLL) substrate 15 coupled to an integrated circuit chip 17. The chip 17 may be molded in encapsulant 19. Underfill 13 may be formed between the chip 17 and the substrate 15.

In accordance with some embodiments, the structure shown in FIG. 1 may be fabricated using DLL substrate process technology. But other fabrication techniques may also be utilized. Moreover, while the illustrated embodiment is a flip chip via stud grid array, flip chip molded via stud grid arrays may also be formed using basically the same techniques.

In some embodiments, ball attach may not be used on the component 12, reducing component 12 costs, shortening the assembly process, improving throughput, and increasing yield. Moreover, solder joint reliability for shock and fatigue cracking may be improved in some embodiments. The use of a via stud may allow three dimensional bonding with solder on the printed circuit board, in accordance with some embodiments, to strengthen the joint and improve resistance to shock failure. At the same time, the via stud may have good fatigue crack resistance, compared to solder, in some cases.

In some embodiments, the interconnection pitch may be scaled to even smaller levels than pitches current technologies. For example, interconnection pitches of less than 0.4 millimeters may be achieved in some embodiments. Referring to FIG. 2, in accordance with some embodiments, a DLL resin core 28 may be formed between two pairs of sandwiched metal foils 24 and 26. In some embodiments, the foils on the top and bottom of the core may be made of copper. A lamination of the foils onto the core may be achieved using a hot press, in one embodiment, so that the foils are embedded and adhere to the core. In some embodiments, one upper and one lower foil is laminated in a first step, followed by the lamination of the second foils on the top and bottom of the core.

Then, as shown in FIG. 2, a glass mask may be utilized, together with a masking material 30, such as photoresist. Upon ultraviolet (UV) light exposure, the masking material 30 is developed where exposed around the glass mask in one embodiment. The material 30 may be a dry film in one embodiment. A stud pattern is created, using the glass mask through exposure of the masking material 30.

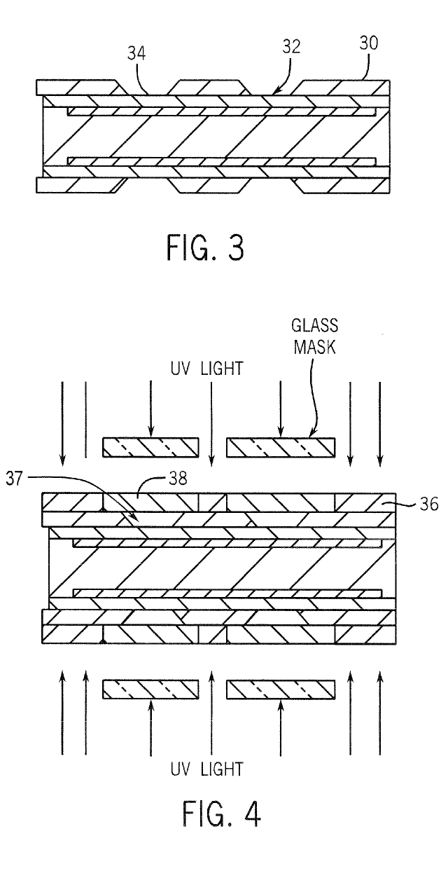

The masking material 30 is developed to reveal the via stud design pattern in the resulting openings 32 that remain under the glass mask, as shown in FIG. 3. A nickel plating may be covered by an electro-less copper plating 34, in one embodiment, as shown in FIG. 3.

Thereafter, as shown in FIG. 4, dry film lamination and UV light exposure creates a via stud design routing. Specifically, a glass mask may be used to block UV light in certain areas 38 of dry film, while exposing the dry film in the areas 36. Cavities 37 remain under the dry film areas 38.

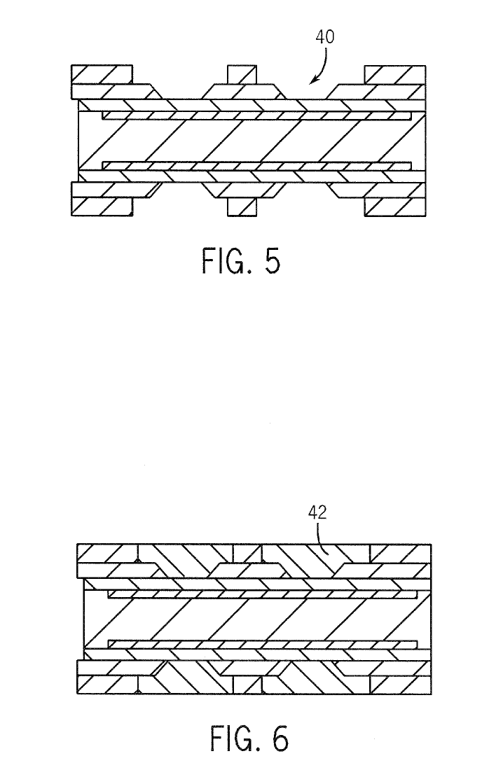

Next, as shown in FIG. 5, the dry film is developed to reveal the via stud design routing 40.

Thereafter, in FIG. 6, an electrolytic copper plating is applied to form the via studs 42 in the openings 40.

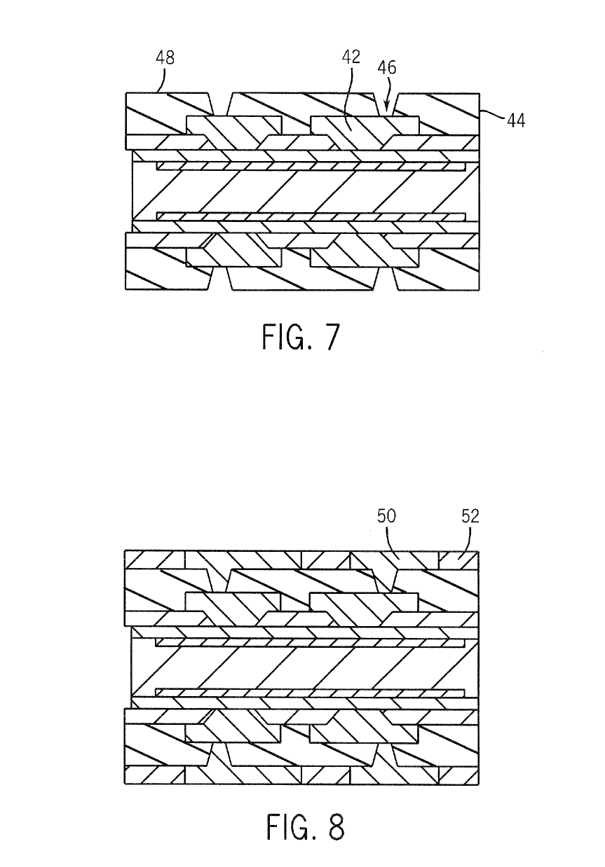

Next, the dry film in areas 36 may be stripped, followed by insulator 44 lamination, as shown in FIG. 7. The insulator 44 may be a build-up film in one embodiment, such as Ajinomoto Build-up Film (ABF). The laminated insulator then may have apertures 46 formed through to the via studs 42. The apertures 46 may be laser vias in one embodiment. Electro-less copper plating 48 may be applied.

Subsequently, dry film 52 patterning is followed by electrolytic copper plating 50 for formation of micro-vias, traces, and planes, as shown in FIG. 8. Next, the dry film 52 is removed by dry film stripping, followed by a quick etch for removing undesired electro-less copper.

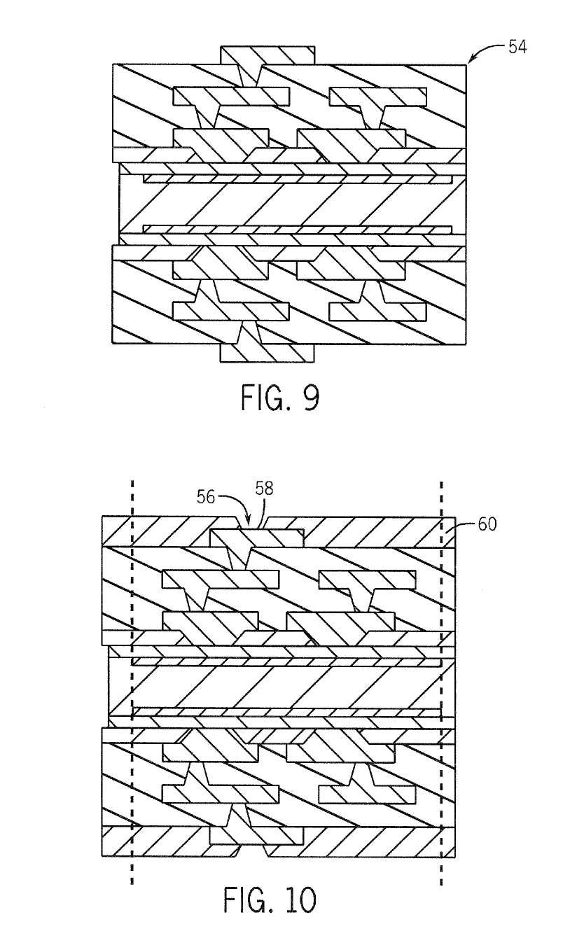

Then, as shown in FIG. 9, the sequence is repeated for forming build-up layers 54 over the layers shown in FIG. 8.

Next, a solder resist coating 60 is applied and an opening 56 is formed therein, as shown in FIG. 10. Nickel, palladium, and then gold plating 58 is formed, within the opening 56, in one embodiment. Subsequently, the panel edges may be cut away, as indicated by dashed lines.

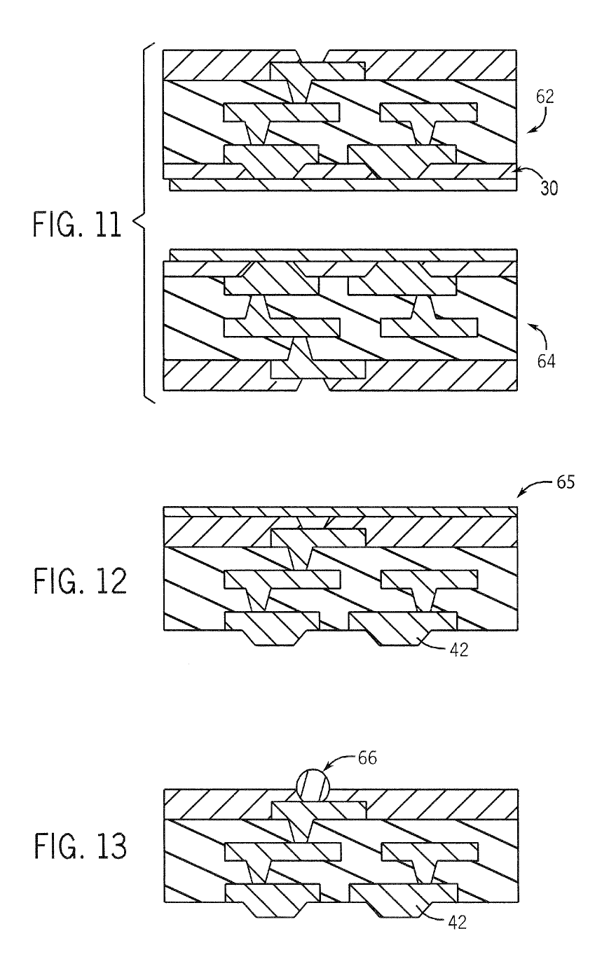

Next, the panels 62 and 64 are separated and the core is removed, as shown in FIG. 11. A protective film lamination 65 is applied, followed by copper etching and nickel etching, as shown in FIG. 12. Then the protective film and dry film are removed to reveal the via stud 42 finish.

Finally, in FIG. 13, a micro-ball or solder bump 66 is attached to form substrate bumps. The bump 66 may be used to secure the integrated circuit chip 12. After underfill 13 and encapsulant 19 is added, the structure is ready for connection.

Thereafter, the structure shown in FIG. 13 may then be attached in a reflow process to a bumped surface, such as a printed circuit board 14, as shown in FIG. 1. During the reflow process, pressure may be applied, in some embodiments, to cause the studs 42 to penetrate into the solder 18 on the board 14.

The studs 42 may include a solderability surface finish that improves solderability. Suitable solderability surface finishes may include, without limitation, organic solderability preservative (OSP), electroless nickel-immersion gold (ENIG), immersion tin, immersion silver, NiPdAu, hot air solder leveling (HASL), electrolytic nickel-hard gold, or electrolytic nickel-soft gold.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a metallic stud protruding from a semiconductor first component;
engaging said stud with solder on a second component; and
reflowing said solder so said stud penetrates and engages said solder to form a solder bond between said components.

2. The method of claim 1 including using direct laser and lamination substrate process technology to form said stud.

3. The method of claim 1 including soldering said components together using an interconnection pitch of less than 0.4 millimeters.

4. The method of claim 1 including applying pressure to at least one of said components to cause said stud to penetrate into said solder.

5. The method of claim 1 including forming solder paste on the second component.

6. An apparatus comprising:
a first component including circuit elements and an array of metallic protrusions coupled to the circuit elements; and
a second component including a plurality of solder portions coupled to said second component and soldered to said protrusions on said first component.

7. The apparatus of claim 6 wherein said array of metallic protrusions has a pitch scalable to less than 0.4 millimeters.

8. The apparatus of claim 6 including a three dimensional bonding between said protrusions and one of said solder portions.

9. The apparatus of claim 6 wherein said protrusions are conical.

10. The apparatus of claim 6 wherein said first component includes an integrated circuit.

11. The apparatus of claim 6, said protrusions including a solderability surface finish.

12. A method comprising:
reflowing solder to couple a first component having a plurality of protruding metallic studs to a second component having a pattern of solder paste matching the pattern of protruding metallic studs; and
causing the studs to penetrate into the solder paste to form a solder bond between said components.

13. The method of claim 12 including soldering said components together using an interconnection pitch of less than 0.4 millimeters.

14. The method of claim 12 including applying pressure to at least one of said components to cause said studs to penetrate said solder paste.

15. The method of claim 12 including connecting a component including studs that are frustroconical.

16. The method of claim 12 including connecting a first component that includes an integrated circuit.

17. The method of claim 12 including forming a three dimensional bond between said studs and said solder paste.

18. An apparatus comprising:
a substrate including semiconductor components; and
an array of metallic protrusions coupled to said semiconductor components, said protrusions protruding from a surface of said substrate, said protrusions to enable external connections to another component.

19. The apparatus of claim 18 wherein said protrusions are arranged with a pitch scalable to less than 0.4 millimeters.

20. The apparatus of claim 18 wherein said protrusions are conical.

21. The apparatus of claim 20 wherein said protrusions are frustroconical.

22. The apparatus of claim 18 wherein said apparatus includes an integrated circuit.

23. The apparatus of claim 18 wherein said protrusions have a solderability surface finish.
